(19) United States
(12) Patent Application Publication
(10) Pub. No.: US 2010/0090265 A1
(43) Pub. Date: Apr. 15, 2010

(54) High density nanodot nonvolatile memory

(75) Inventors: Arup Bhattacharyya, Essex Junction, VT (US); Warren M. Farnworth, Nampa, ID (US); Paul A. Farrar, Bluffton, SC (US)

Correspondence Address: SCHWEGMAN, LUNDBERG & WOESSNER, P.A., P.O. BOX 2938, MINNEAPOLIS, MN, 55402, US

(73) Assignee: Micron Technology, Inc.

(21) Appl. No.: 11/583,336

(22) Filed: Oct. 19, 2006

(51) Int. Cl. H01L 29/788; H01L 21/336

(52) U.S. Cl. 257/315; 438/257; 977/742; 257/E29.3; 257/E21.409

(57) ABSTRACT

A nanodot nonvolatile memory element comprises a substrate having a source and a drain region formed therein, and an insulating layer formed on the substrate. The insulating layer contains a nanocrystalline floating gate of approximately three to six nanometers in diameter formed at a distance of approximately two to five nanometers from the substrate, and a carbon nanotube control gate having a diameter of approximately six nanometers or less is formed at a distance of approximately 10-15 nanometers from the substrate.

### FIELD OF THE INVENTION

The invention relates generally to electronic memory, and more specifically to a high density nanodot nonvolatile memory.

### BACKGROUND

Computers and other electronic systems that handle or process information often need to store the information for a period of time while working with it. Some information is stored in volatile memory such as the dynamic random access memory that is commonly used in personal computers, while other information is stored in a more permanent way such as in hard disk drives, CD-ROM or DVD, or other long-term storage that is typically high in capacity but slow relative to most memory systems. Dynamic random access memory is characterized as volatile because data stored in such memory typically is lost when power is removed, while data stored on a hard disk drive, CD-ROM or other such storage is typically retained for a significant time in the absence of power. Some types of data storage resemble memory in their structure and operation, but are not volatile and are known as nonvolatile memories.

A variety of computer systems and electronic devices store information in such memory that is not volatile, or does not lose its content when power is disconnected. These nonvolatile memories can be reprogrammed, read, and erased electronically, and are particularly well suited to storing information such as music in digital audio players, pictures in digital cameras, and configuration data in cellular telephones. One such nonvolatile memory is commonly known as flash memory, named in part because a flash operation is used to erase the content of a block of data before it is reprogrammed, and is packaged for consumer use in products such as CompactFlash memory cards, USB flash memory drives, and other such devices.

Flash memory comprises a number of cells, each of which typically stores a single binary digit or bit of information. A typical flash memory or nonvolatile memory cell comprises a field effect transistor having an electrically isolated floating gate that controls electrical conduction between source and drain regions of the memory cell. Data is represented by a charge stored on the floating gate, and the resulting conductivity observed between the source and drain regions.

Modern flash memory cells therefore require a transistor structure including a floating gate for each bit or binary element of information stored, as well as a series of transistors used to select or access specific memory bits or words. The size and power required to operate these nonvolatile memories is therefore not trivial, and imposes limits on the physical size and capacity of a nonvolatile memory. Further, degradation of operational elements such as the tunneling of electrons onto and off of the floating gate in a nonvolatile memory cell can change the operating characteristics of nonvolatile memory over time, limiting its reliability and useful life.

Improvements in many aspects of nonvolatile data storage, including density, capacity, power consumption, and reliability are therefore desirable.

### BRIEF DESCRIPTION OF THE FIGURES

FIG. 1 shows a nonvolatile flash memory cell, consistent with the prior art.

FIG. 2 shows a nanocrystalline nonvolatile memory element, consistent with an example embodiment of the invention.

FIG. 3 shows a string of coupled nanocrystalline nonvolatile memory elements coupled to a bitline and a source, consistent with an example embodiment of the invention.

FIGS. 4A-4D show an example method of forming a string of nanocrystalline nonvolatile memory elements such as were shown in FIG. 3, consistent with an example embodiment of the invention.

FIG. 5 shows a top view of a nanocrystalline nonvolatile memory array, consistent with an example embodiment of the invention.

FIG. 6 is a cross section view of the nanocrystalline nonvolatile memory array of FIG. 5, showing masking and formation of bitline carbon nanotube studs, consistent with an example embodiment of the invention.

FIG. 7 is a cross section view of the nanocrystalline nonvolatile memory array of FIG. 5, showing masking and formation of wordline nanotube studs, consistent with an example embodiment of the invention.

FIG. 8 is a top view of the nanocrystalline nonvolatile memory array of FIG. 5, showing formation of carbon nanotube wordlines, consistent with an example embodiment of the invention.

FIG. 9 is a top view of the nanocrystalline nonvolatile memory array of FIG. 5, showing formation of carbon nanotube bitlines, consistent with an example embodiment of the invention.

FIGS. 10A-10K are cross sections of a memory array, illustrating a method of fabricating self-aligning vertical nanotubes to form contact connections, consistent with an example embodiment of the invention.

### DETAILED DESCRIPTION

In the following detailed description of example embodiments of the invention, reference is made to specific examples by way of drawings and illustrations. These examples are described in sufficient detail to enable those skilled in the art to practice the invention, and serve to illustrate how the invention may be applied to various purposes or embodiments. Other embodiments of the invention exist and are within the scope of the invention, and logical, mechanical, electrical, and other changes may be made without departing from the scope or extent of the present invention. Features or limitations of various embodiments of the invention described herein, however essential to the example embodiments in which they are incorporated, do not limit the invention as a whole, and any reference to the invention, its elements, operation, and application do not limit the invention as a whole but serve only to define these example embodiments. The following detailed description does not, therefore, limit the scope of the invention, which is defined only by the appended claims.

One example embodiment of the invention provides a nanodot nonvolatile memory element comprising a substrate having a source and a drain region formed therein, and an insulating layer formed on the substrate. The insulating layer contains a nanocrystalline floating gate of approximately three to six nanometers in diameter formed at a distance of approximately two to five nanometers from the substrate, and a carbon nanotube control gate having a diameter of approximately six nanometers or less is formed at a distance of approximately 10-15 nanometers from the substrate. The terms floating gate and floating node are used interchangeably for purposes of this application, and the terms gate, node, and other terms that may be used in the claims are not limited by the examples presented here. In a further embodiment, at least one of the carbon nanotube control gate and the nanocrystalline floating gate are formed via a mask that is formed via self-aligning chaperonin proteins.

Current nonvolatile flash memories are constructed using features in the micron or micro-meter range in size. For example a 0.5 micron process features elements such as conductive lines, transistor components, and other features having widths as small as half a micrometer. While these sizes are extremely small by the standards of only a few decades ago and have enabled much of the power, portability, and performance of electronic devices such as portable computers, cell phones, portable digital music players, and the like, there is a demand for even smaller electronic components. One such example is demand for higher capacity storage that takes less space to store the same amount of data, or that can store significantly more data in the same space. Such a technology might enable storage of hundreds of movies on a portable digital media player that today is capable only of storing hundreds of songs, or enable storage of very large volumes of information such as detailed weather simulation data over a long period of time.

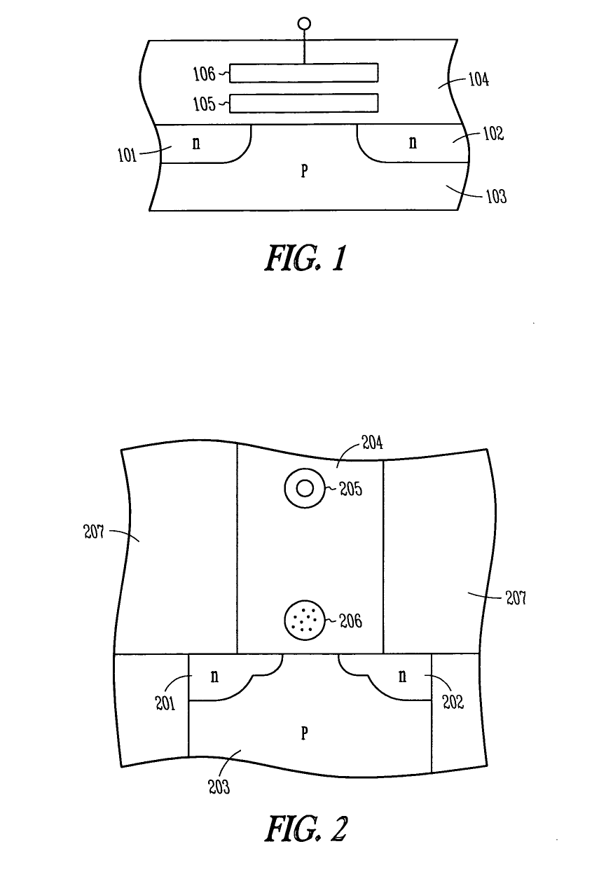

Some embodiments of the invention seek to provide higher storage capacity by providing nanodot or nano-scale nonvolatile memory elements, or memory elements that are measured in nanometers or fractions of nanometers and that are significantly smaller than today's micron-size memory elements. To further illustrate the differences between traditional lithography-formed micron scale semiconductors and nano-sized devices, a prior art flash memory element is illustrated in FIG. 1.

FIG. 1 illustrates an example of a flash memory or nonvolatile memory cell, which shares a basic structure with an EEPROM or electronically erasable programmable memory. A source 101 and drain 102 are formed on a substrate 103, where the substrate is made of a p-type semiconductor material. The source, drain, and substrate are in some embodiments formed of silicon, with a dopant having five valence electrons such as phosphorous, arsenic, or antimony to increase the electron concentration in the silicon or with a dopant having three valence electrons such as boron, gallium, indium, or aluminum to increase the hole concentration. Dopants are added in small, controlled quantities to produce the desired hole or electron concentration in the semiconductor material, resulting in n-type material if a surplus of electrons are present, such as in the source 101 and drain 102, and resulting on p-type material if an excess of holes are present such as in the substrate material 103.

An insulator material such as silicon oxide (SiO2) is used to form an insulating layer 104, which has embedded within it a floating gate 105, fabricated from a conductor such as metal or polysilicon, and a control gate 106 similarly formed of a conductive material. The floating gate is not directly electrically coupled to another conductive element of the memory cell, but is “floating” in the insulating material 104. The floating gate is separated from the region of the p-type substrate material 103 between the source 101 and the drain 102 by a thin insulative layer of controlled thickness, such as 0.01 micrometers.

In operation, the floating gate 105 is able to store a charge due to its electrical isolation from other components of the memory cell. Setting or erasing a charge level on the floating gate 105 is performed via a tunneling process known as Fowler-Nordheim tunneling, in which electrons tunnel through the oxide layer separating the floating gate 105 from the substrate 103. Most flash memory cells are categorized as NOR flash or NAND flash, based on the parallel (NOR) or serial (NAND) arrangement of memory cells and the circuitry used to perform write, read, and erase operations.

To write a bit to a NOR flash memory cell as shown in FIG. 1, or to store a charge on its floating gate, the source 101 is grounded and a supply voltage such as six volts is applied to the drain 102. In one embodiment, the drain voltage is applied via a bitline used to identify the bit to be written. A higher voltage such as 12 volts is also placed on the control gate 106, forcing an inversion region to form in the p-type substrate due to the attraction of electrons to the positively charged control gate. The voltage difference between the source and drain in combination with the inversion region in the p-type material result in significant electron flow between the source 101 and drain 102 through the p-type substrate 103's inversion region, such that the kinetic energy of the electrons and the electric field generated by the control gate voltage at 106 result in Fowler-Nordheim tunneling of high-energy or “hot” electrons across the insulator and onto the floating gate 105.

The floating gate thereby adopts a negative charge during the write process that counteracts any control gate positive charge's effect on the region of the substrate 103 between the source 101 and drain 102, raising the memory cell's threshold voltage that must be applied to the wordline to result in conduction across an inversion region in the p-type substrate material 103. In other words, when the wordline's voltage is brought to a logic 1 or high voltage such as five volts during a read operation, the cell will not turn on due to the higher threshold voltage caused by the electrons stored on the floating gate 105 during the write operation. The read voltage applied to the control gate is larger than the threshold voltage (Vt) of an erased memory cell, but not large enough to allow conduction across a substrate 103 inversion region of a cell that has been written.

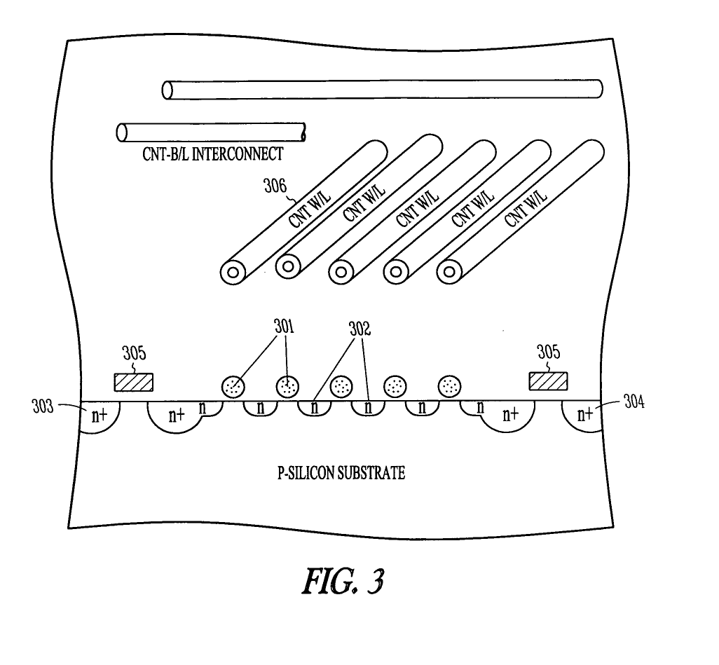

NAND memory cells are organized in strings or chains of series memory cells, such as a chain of 32 cells coupled between a source line and a bit line as illustrated in FIG. 3. To write a NAND flash memory cell, the source 301 is grounded, and drain 302 of the string of FIG. 3 along with all the control gates not to be written are held at appropriate potentials such that the channel below the “standby” gates is inverted. The specific control gate of the cell to be written, 306, is brought to a higher voltage of perhaps 20 volts. Charges are injected from the channel only to the specific bit to be written by tunneling, while other bits in the string remain in a standby condition. The control gate voltage is significantly higher than the 12 volt control gate voltage used to program the same memory cell using NOR flash methods, because a higher voltage is needed in the absence of “hot” electrons flowing between the source and drain of the memory cell.

To erase a memory cell using typical NOR flash memory circuitry, a similar tunneling of electrons takes place from the floating gate to the source 101 of the memory cell. The source is in some embodiments more deeply diffused than the drain to enhance erase performance. A positive voltage such as twelve volts is applied to the source 101, the control gate 106 is grounded, and the drain 102 is left disconnected to perform an erase in one example. The large positive voltage on the source 101 attracts the negatively charged electrons, causing them to tunnel through the insulating layer 104 and leave the floating gate. Because there is relatively little current flow between the source and drain during an erase operation, performing an erase takes very little current and consumes relatively little power. In typical flash memory erase operations, a block of bits is erased at the same time, and the power consumed depends on the size of the block erased.

In another example of memory cell erase often used in NAND memory configurations, the source 301 and drain 302 are left floating, but the substrate material 303 is brought to a high positive voltage such as 20 volts, attracting the negatively charged electrons and causing them to tunnel from the floating gates through the oxide insulating layer 304 to the substrate material 303. This method is sometimes known as “channel erase”, because the channel substrate material 303 receives electrons from the floating gate.

The floating gate of a typical prior art nonvolatile memory cell such as that of FIG. 1 is programmed with on the order of a thousand electrons, and is of a width that is either in the single digit micrometer range, or a significant fraction of a micrometer such as 0.5 micrometers. In contrast, one example embodiment of a nanodot nonvolatile memory comprises a floating gate element that comprises a nanocrystal that stores only one or two electrons when charged, and is of a width in the range of five nanometers. Further, the pitch between such nano-sized memory elements can be significantly reduced, in the range of five nanometers in one example, increasing the amount of memory that can be created on a given size of memory device a hundredfold or more.

FIG. 2 shows one such example of a nanodot NOR nonvolatile memory cell, consistent with an embodiment of the present invention. The lower portion of the nonvolatile memory cell strongly resembles the lower portion of the flash memory cell of FIG. 1, including a source 201, a drain 202, and a substrate material 203 manufactured from doped silicon. A dielectric material 204 such as hafnium aluminum oxide (HfAlO) in this example supports a control gate comprising a carbon nanotubes, and a floating node comprising a germanium, silicon, or germanium/silicon nanocrystal 206. HfAlO is chosen here as a high-K insulating dielectric material due to its electron barrier energy of 1.7 eV, band gap of approximately 6 eV, and K of approximately 17. This dielectric embeds a silicon or silicon-germanium nanocrystal floating node, and is selected based on two criteria. First the electron barrier energy is above 1.5 eV, and so has desirable charge retention characteristics. Second, the K value is high enough for relatively low programming voltages on the order of 10V or less. Other insulators such as SiO2, which has a relatively low K value of 3.9, can result in a significantly higher programming voltage, even if its electron barrier energy of 3.2 eV provides suitable charge retention. These concerns can be particularly important in some embodiments when only one or two electrons are stored in a programmed or charged floating node nanodot.

The carbon nanotube control gate 205 of this example is on the order of five nanometers in diameter, just as the nanodot crystal of this example is on the order of five nanometers in diameter. The distance between the carbon nanotube control gate 205 and the nanodot crystal floating node is on the order of 10 nanometers, and the distance between the nanodot crystal floating node and the silicon surface of substrate 203 is approximately 2-3 nanometers. In a further embodiment, self-capacitance of the device is reduced by isolating the gate region of the nanodot memory device with a surrounding SiO2 gate region isolation insulator, such as is shown at 207, and the source 201 and drain 202 regions of the transistor are made very shallow. The resulting reduction in self-capacitance of the memory device is important to ensure an adequate memory retention window for the device.

The gate region insulator 207 and the dielectric insulator material 204 have various compositions in various embodiments of the invention, including using single or multiple layers of different insulating materials to tailor device characteristics. For example, HfO2, SiC, GeC, GeC, LaAlO3, HfSiON, and SiO2 each have different electron barrier energies, and can be used alone, in layers, or in combination within the same layer to effectively control programming voltage, programming speed, and charge retention by altering the effective barrier energy and tunnel distance of injected electrons. Similarly, tailoring the insulating layer between the nanocrystalline floating node 206 and the carbon nanotube control gate 205 allows additional control of the programming voltage and self-capacitance of the memory element.

In operation, a programming voltage of approximately five to ten volts applied to the control gate using NOR programming methods to attract “hot” electrons, which are provided by grounding the source 201 and applying a supply voltage such as two to five volts to the drain 202. The nanodot memory element can also be programmed using NAND flash methods, such as by grounding the source and drain 201 and 202, and applying a higher voltage such as 15 volts to the carbon nanotube control gate 205. The applied control gate voltage is higher using NAND programming methods, due to the absence of “hot” or high-energy electrons flowing between the grounded source and drain.

The number of electrons on the nanocrystal floating node and the node's retention of electrons is influenced by various quantum mechanical principles, due in part to the very small size of the nanocrystalline floating node. When the floating node acquires a first surplus electron or charge, the electron repels other electrons due to the electric field surrounding the negatively charged particles associated with the electrostatic repulsion of like-charged particles. The energy the second electron needs to tunnel into the floating node is therefore somewhat greater than the energy needed by the first tunneling electron, making placement of a large number of negatively charged electrons in a very small space difficult. Even should several electrons tunnel and reside in a nanocrystalline floating node dot on the order of five nanometers, the proximity of the electrons to one another results in great enough repulsive forces for the electrons to tunnel back to the source or drain, resulting in an average of no more than a few electrons in the floating node.

Although a greater number of electrons in the nanocrystalline floating node dot would be easier to detect and make reading the state of the programmed memory cell more certain and reliable by causing a greater threshold shift for conduction across the substrate between the source and drain of the memory element, principles of quantum mechanics and electrostatics limit the charge that can reside in a nano-sized floating node. Some embodiments of the invention will therefore typically have floating node programmed state charges of only one or two electrons, rather than the thousands of electrons typically present in conventional lithography-produced nonvolatile memory devices.

Arrays of nanodot or nanocrystal floating node nonvolatile memory can be manufactured using the basic nanodot structure of FIG. 2 as discussed above for both NOR and NAND memory configurations. An example NAND configuration for such a memory device is illustrated by the three serial devices comprising part of a NAND nonvolatile memory string shown in FIG. 3. NAND nonvolatile memory cells are typically arranged in arrays made up of strings of memory elements that are addressed via wordlines and by common source lines and bitlines. FIG. 3 shows a portion of a NAND array of nanodot nonvolatile memory coupled to a single bitline, where each of the memory cells shown in the selected bitline is further selectable via a wordline.

A series of nanodot or nanocrystal germanium floating nodes 301 are configured in a chain between a series of source and drain elements 302, where the chain is selected for operation by coupling to the bitline 303 and source line 304. The chain can therefore be selectively addressed or isolated from the source line 304 and bitline 303 by line select transistors 305.

To perform a read operation, the word line 306 of the selected memory cell is maintained at a low but positive voltage level while the word lines of unselected memory cells are brought to a sufficiently high voltage to cause the unselected memory node to conduct irrespective of any charge that may be on the floating nodes of the individual memory cells. If the selected memory cell has an uncharged floating memory node it will activate as a result of the low positive voltage level on the wordline, but if the nanocrystal floating node has a negative charge it will raise the threshold voltage of the selected memory cell above the low positive voltage applied to the control gate such that the cell does not conduct. The state of the memory cell's floating node can therefore be determined by monitoring conductivity or current flow between the common bit line and source line.

To perform a write operation, the bitline 303 is held at a selected voltage and the source line 304 is typically grounded via line select transistors 305 coupling the chain to a grounded source line 304 and powered bitline 303. The wordlines of the memory cells not being written are brought to a sufficiently high voltage to cause the memory cells to conduct irrespective of their floating gate charges or memory states, such as five to ten volts. The selected memory cell's wordline 306 is coupled to a significantly higher voltage, such as 15-20 volts. The voltage applied to the selected memory cell's wordline causes formation of an inversion region in the substrate channel and tunneling of electrons due to the attraction of electrons to the positively charged control gate coupled to the high voltage signal. The grounded source in combination with the inversion region in the substrate material provide a source for one or two electrons to tunnel in the memory cell's inversion region, causing electrons to inject across the insulator barrier due to the high electrical field present and becoming trapped on the nanocrystal floating node.

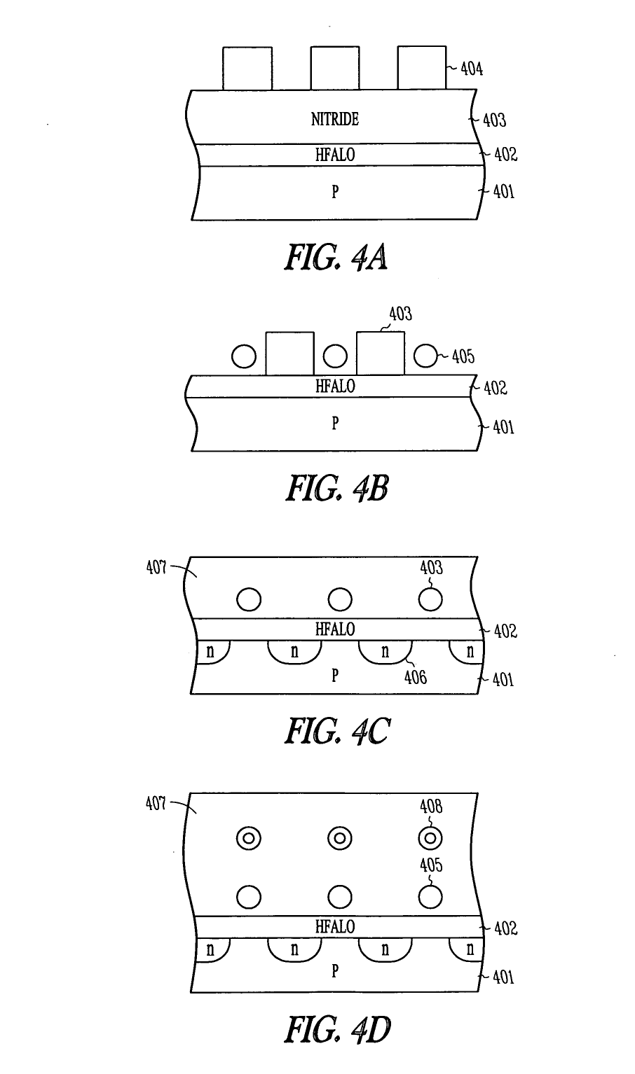

In the example memory array of FIG. 3, the carbon nanotube wordlines that serve as control gates for the nanodot memory elements are approximately 10 nanometers apart center-to-center, as are the n-type diffusion regions in the p-type substrate and the nanodot memory elements. Accurate formation and consistent geometry in positioning such small-scale elements is an important factor in ensuring consistent and reliable operation of the memory elements, and is addressed in one example shown in FIG. 4.

FIG. 4A shows formation of the initial layers, including the p-type silicon substrate 401, the HfAlO layer 402, a hard nitride mask layer 403, and a self-aligned Chaperonin protein layer 404. After formation of the p-type substrate and isolation of the area to be processed, the tunnel dielectric layer of HfAlO is formed such as by sputtering, chemical vapor deposition, or other suitable processes. The assembly is then annealed or heated, to reduce stresses and density of interface states, fixed charges, and other interface anomalies between the two layers.

Next, a nitride or other hard mask layer 403 is formed on the HfAlO tunnel dielectric layer, and a protein mask is formed by transferring a pattern array of small proteins known as chaperonins 404 to the surface of the nitride. In one such example, a tunnel oxide layer immersed in a chaperonin protein bath will result in a protein assembly of chaperonins on the order of 10 nanometers apart, which can be used as a self-assembly template for uniform nanocrystal distribution. Further, the proteins are able to each capture a nanocrystal, aiding in alignment and placement of nanocrystals in some fabrication examples. Here, the self-aligned chaperonin proteins 404 are formed on the surface of the nitride, but in other embodiments they are formed on other surfaces, or the pattern they form is used to create a pattern or self-assembled lithography template applied to the nitride layer 404 of FIG. 4A.

The nitride is then etched to expose the tunnel dielectric layer 402 in areas where the self-aligned chaperonin proteins don't mask the nitride layer, forming nitride peaks 403 such as are shown in FIG. 4B. Germanium nanocrystals 405 are then placed on the exposed tunnel layer 402, which form an array as a result of the self-alignment pattern of the chaperonin proteins. Once the crystals are placed, the nitride layer can be selectively etched or otherwise removed such as by chemical processes, and the nanocrystals 405 that will become the floating nodes and that will function as masks for ion implantation that forms the n-type silicon shallow wells 406 at FIG. 4C.

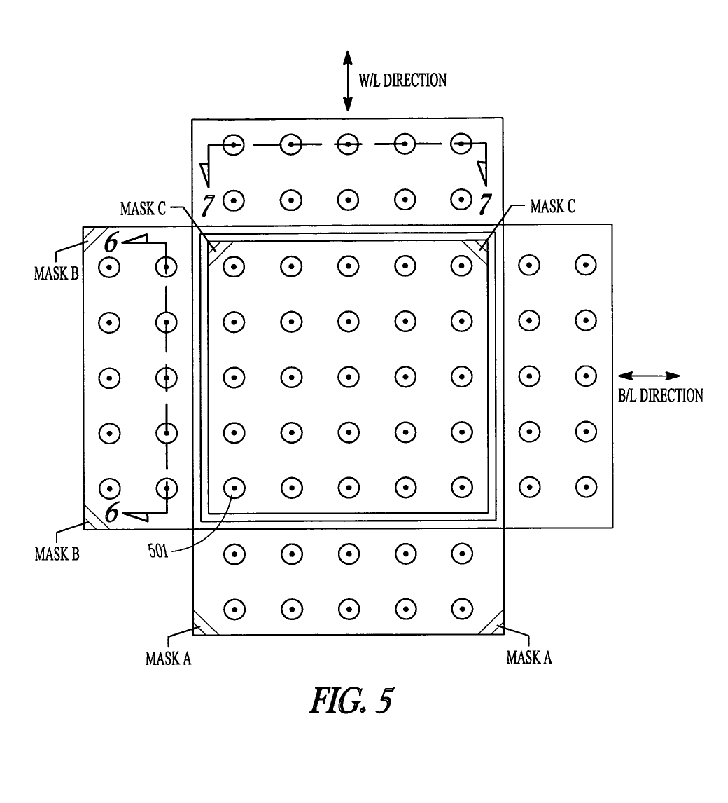

A thicker layer of HfAlO is then formed as shown at 407, which serves to separate the nanocrystal floating gates 405 from the carbon nanotube control gates or wordlines 408, shown in FIG. 4D. The control gate carbon nanotubes are self-aligned to the same geometry as the nanocrystal floating gates, such as by using chaperonin protein masks to place the carbon nanotubes on the HfAlO tunnel insulation layer 407. Other steps, such as annealing the assembly of FIG. 4D, depositing a metal connect layer over the insulation layer 407 to couple the carbon nanotube control gate lines to control logic, and other such steps will also be performed in various further examples. Formation of the carbon nanotube wordlines is shown in greater detail in FIGS. 5-7.

FIG. 5 shows a top view of an array of nanodot floating gates for a nonvolatile memory array, such as were formed and shown in FIG. 4B. In this stage, the chapreonin protein mask has been used to etch the nitride layer and the chaperonin has been removed such as by heat, leaving an array of nitride and nanocrystalline floating node elements 501. This top view also serves to illustrate the direction of formation of wordlines and bitlines, as will be shown in further figures in greater detail. The masks used to define these various stud-connections are identified as A, B, and C in FIG. 5. Mask C isolates and defines the array regions while masks A and B include elements of the array and the peripheral regions parallel to the word lines and bitlines respectively.

FIG. 6 shows the peripheral cross-section of studs perpendicular to the bit lines. Interconnecting carbon nanotube studs are aligned with deep bitline diffusions 602 and isolated from neighboring studs by nitride isolation 601. Diffusion of an n-type material such as arsenic or phosphorous as shown at 602 forms n-type regions in the p-type substrate, forming source lines and bit lines for select transistors as were shown in conjunction with control gates 305 and bitline 303 and source line 304 diffusions in FIG. 3. Electrical connection studs are formed by application of Ti-silicide and nickel as shown at 603, which serve to join the n-type diffusion regions 602 to carbon nanotube studs 604. The nitride is then removed such as by selective etch or chemical etching, and the studs remain as shown in the lower portion of FIG. 6.

Wordlines are similarly coupled to the array by using a mask to form electrical contacts and studs, as is shown in FIG. 7. Here, the nitride mask 701 has voids where a combination of copper, titanium, and nickel are deposited on the oxide layer at 702, serving as an electrical connection to carbon nanotube wordlines. In one example, copper is first deposited on the exposed oxide surface, forming a film of approximately 300 nm. Titanium is then formed on top of the copper in a thickness of approximately 50 nm, and nickel is formed on the titanium layer in a thickness of approximately 10 nm. Carbon nanotubes are then formed over the vias that contain nickel as a catalyst, resulting in formation of a series of carbon nanotube wordline studs electrically connecting various control electronics to the wordlines to be formed of carbon nanotubes as shown at 306 of FIG. 3.

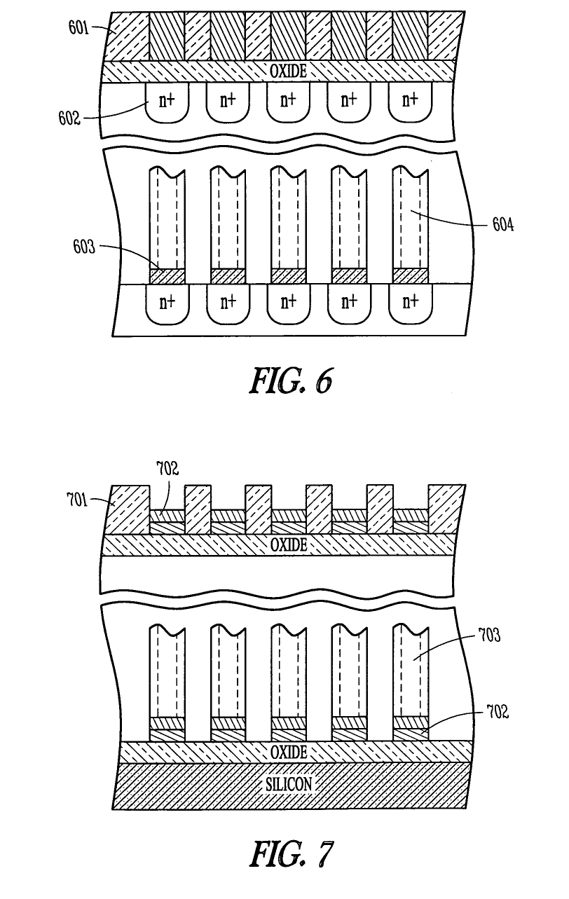

FIG. 8 shows a top view of such carbon nanotube wordlines, consistent with an example embodiment of the invention. Viewed from the top as in FIG. 5, the carbon nanotube wordlines 801 are shown formed in alignment over nanocrystal floating node elements 802. The wordline carbon nanotubes 801 are further coupled to control electronics such as a read amplifier and word select logic using the carbon nanotube studs formed using the mask as shown in FIG. 7, which is not pictured in FIG. 8.

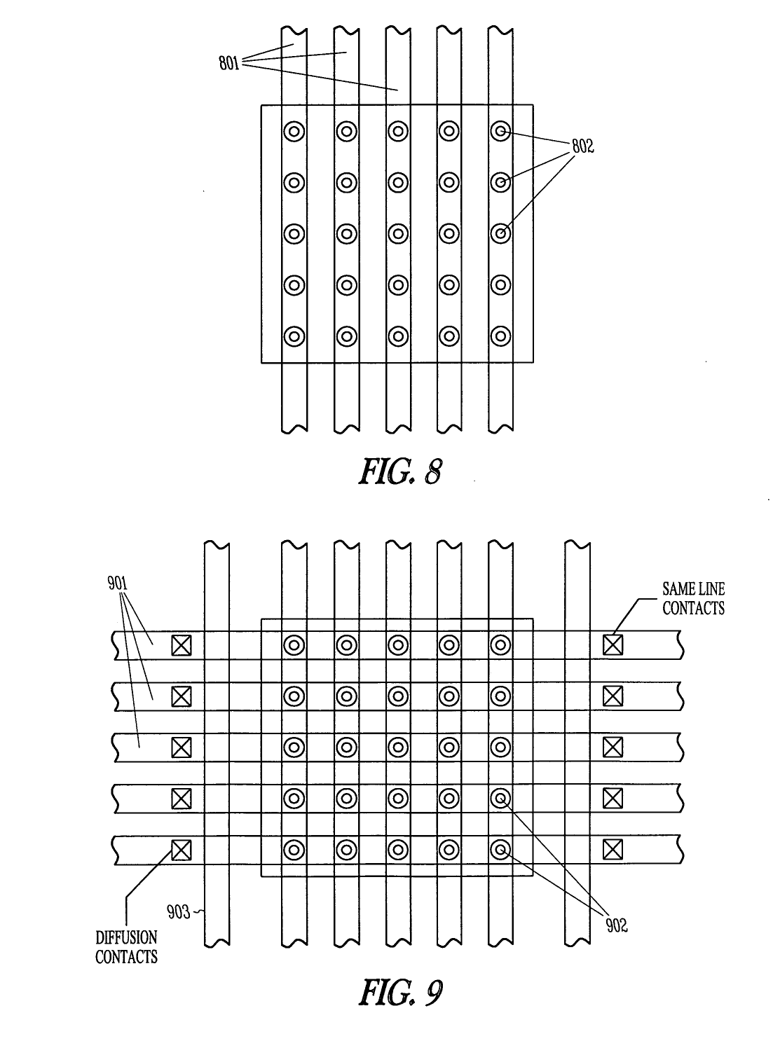

Similarly, in FIG. 9, the bitline connecting studs formed as shown in FIG. 6 are exposed, and bitlines are formed of carbon nantobues as shown at 901, aligned with the nanodot floating nodes 902. The bitlines are coupled via activation of bitline and source line select gates 903 to the various voltage signals supplied to the bitlines and wordlines via diffusion contacts 904, coupling the bitlines and source lines to control logic to perform operations such as reads, erases, and writes. In this example, once the bitline studs are exposed they are grown taller before an oxide insulation layer is formed and the taller carbon nanotube bitline studs are again exposed, at which point the carbon nanotube bitlines 901 are formed to connect the bitline studs.

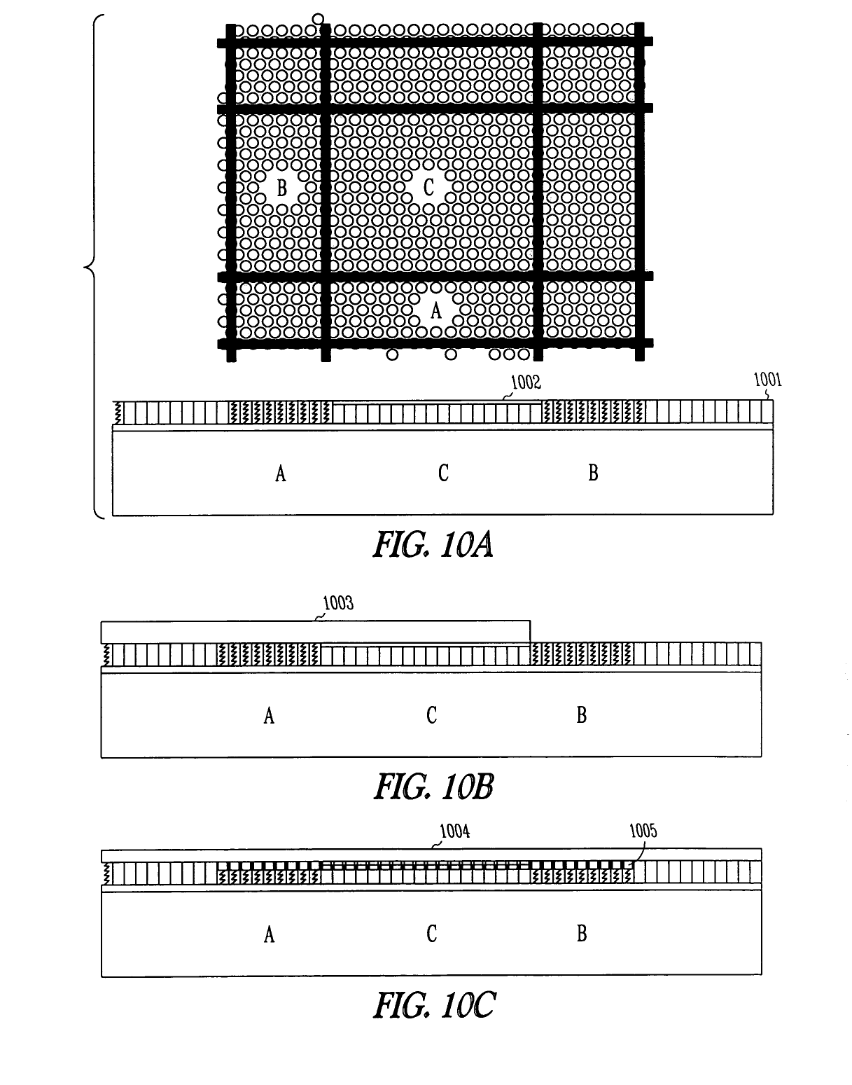

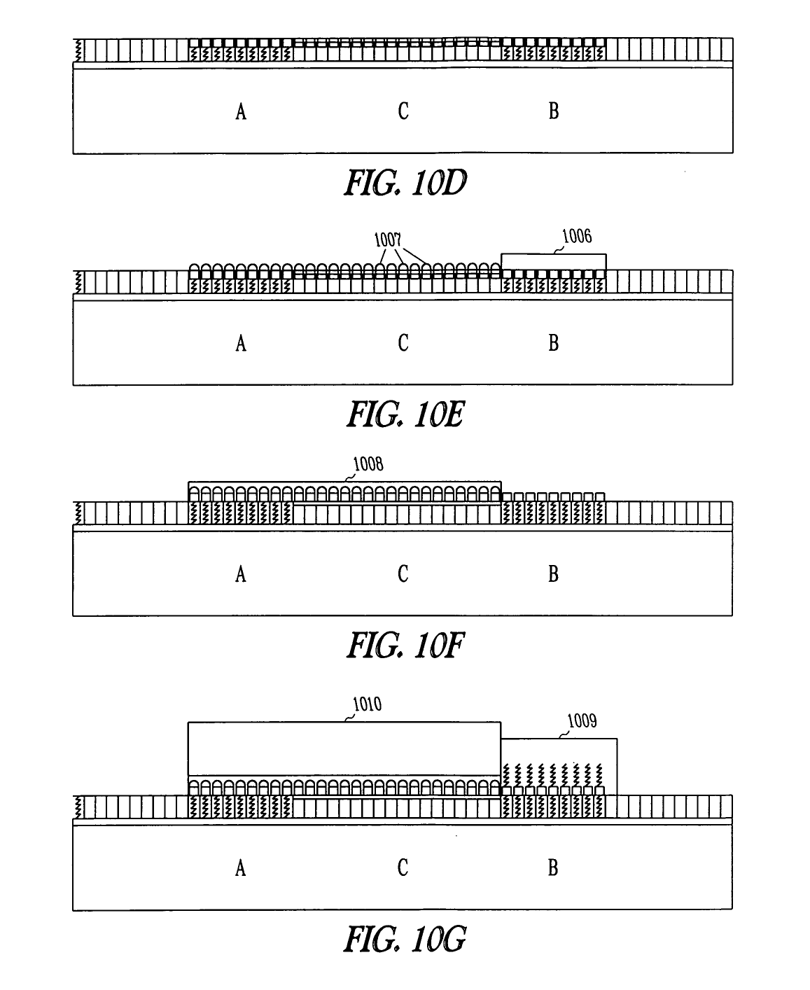

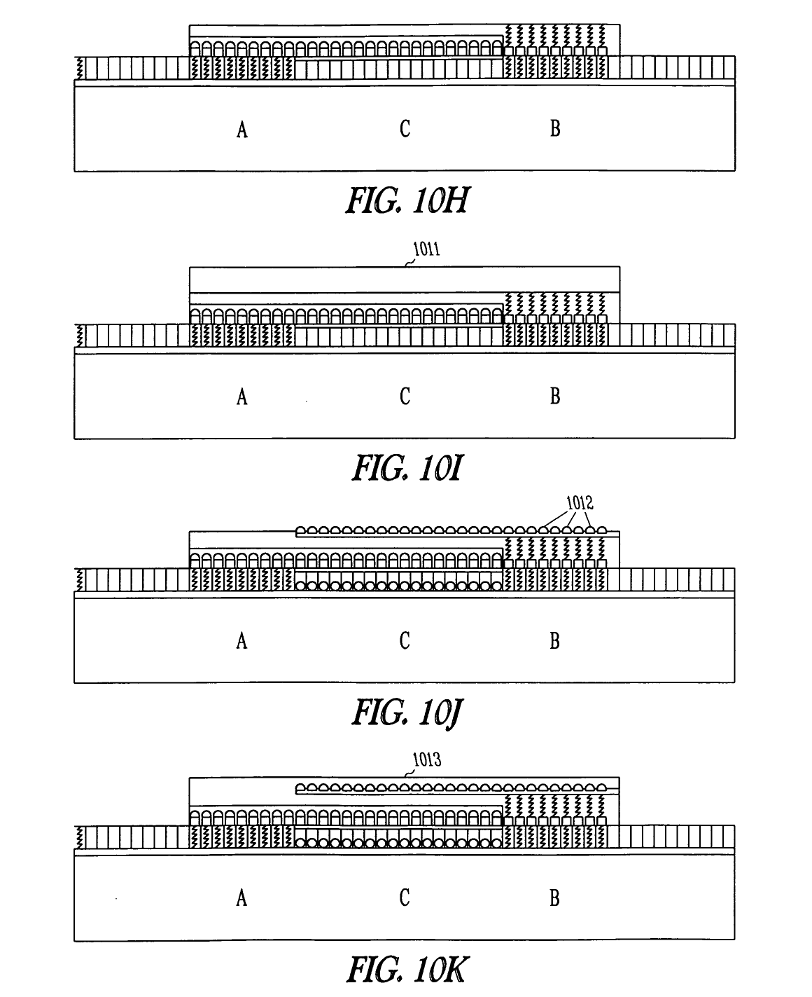

FIGS. 10A-10K illustrate a method of fabricating self-aligning vertical nanotubes to form contact connections on a memory array, consistent with an example embodiment of the invention. In FIG. 10A, regions A, B, and C were covered with Hafnium Aluminum Oxide or another material, covering the nanotube formations in the nitride layer 1001. Chemical mechanical polishing or another suitable method is used to remove the Hafnium Aluminum Oxide from regions A and B, leaving a layer covering only region C as shown at 1002 and exposing the carbon nanotube vias in regions A and B.

In FIG. 10B, The A and C sections are covered or masked as shown at 1003, leaving only region B's carbon nanotubes exposed. The wafer is then exposed to an Oxygen O2 plasma, which will reduce the height of the exposed carbon nanotubes in region B. In FIG. 10C, an electron beam forms trenches in the patterned nitride coating 1003 covering the A section and crossing the C section, to create paths to be used for word line formation. Tungsten 1004 and a precursor seed of Nickel 1005 are applied over the wafer. In FIG. 10D, a chemical mechanical polish operation polishes the tungsten and precursor seed layers applied in FIG. 10C, leaving precursor seed in the precursor paths formed in 10C and on the vertical nanotube vias in region B.

In FIG. 10E, the B section is coated with a protective coating or mask layer 1006, and the wafer is exposed to a carbon nanotube growth environment to create horizontal carbon nanotube structures 1007. The formed horizonatal carbon nanotube structures are covered with a protective layer at 1008, and the protective coating covering section B is removed such as via chemical mechanical polishing to expose the carbon nanotubes and Nickel seeds in section B. FIG. 10G shows growth of new vertical carbon nanotubes from the exposed Nickel seed contacts at 1009, and coating of the wafer with a protective insulating layer 1010.

Part of the insulating layer 1010 is removed in FIG. 10H, exposing the vertical nanotubes 1009. The vertical bitline contacts are coated over by a uniform coat 1011, and electron beam trenches are formed over the B section to form precursor paths for the bitlines to be formed. Tungsten and a precursor seed of Nickel are deposited over the wafer to receive the carbon nanotube bitline connections to be grown. In FIGS. 10J and 10K, rotated ninety degrees from the previous FIG. 10 illustrations, and the carbon nanotube bitlines 1012 are formed. A protective coating 1013 covers the carbon nanotube bitlines, protecting the top of the memory array and connection assembly.

The extremely high density of storage which can be achieved by the structures previously presented will pose some very difficult problems in the wiring and insulation of these devices. It is desirable to provide low resistivity in the metallurgy and also provide a highly electromigration resistant conductor. The resistance will be a function of both the wiring structures and the metal to silicon and the metal to metal contact resistance. The contact resistance will be a function of both photo-lithographic processing and the contact metallurgy. In order to improve the contact resistance of the metallurgy it is desirable that the metal which is making the contact be able to reduce any residual oxides present, i.e. reduce SiO2. This can be achieved by using a layer of ether Titanium, Zirconium or Hafnium as the contact material. The reason for this selection is the high solubility of oxygen in the metallic phase. For example the solubility of Oxygen in Titanium is approximately 10 at. % at 400 C and 33 at % above 600 C. Similar or higher solubilities of oxygen are found in the case on Zirconium and Hafnium. These solid solutions are all thermodynamically able to reduce SiO2 to a significant extent.

The choice of metallurgy will be made in one embodiment depending upon the final lithographic dimensions used for the first level metal. For extremely high density first level metal an Aluminum based metallurgy will be preferred, due to the lower intrinsic electron scattering of Al in contrast to Copper. This is of little consequence at larger dimensions, but for dimension of the order of the example presented here it becomes a factor in design. Although the resistance of copper is less than Aluminum in larger lines, the same does not hold true for extremely fine conductive lines. Depending upon the array size and performance requirements it may be desirable to strap the word lines with the first metal level. The first metal level can be ether Ti—AlCu—Ti or Zr—Cu— (cap). Depending upon the absolute pitch of the metallurgy used. If a Aluminum based metallurgy is used the contact metallurgy serves both to reduce contact resistance and improve electromigration resistance. As all three reactive metals have very low solubility in Aluminum, their effect on the line resistance will be similar.

In the example using Al Cu metallurgy the process will be as follows:

### 1. open contacts

### 2. Deposit the Ti Layer

### 3. Co-deposit Al-3% Cu

### 4. Deposit Ti

### 5. RIE The final film

### 6. Deposit Insulating level

If a Cu metallurgy is desired it may be deposited by either electro or electroless plating. In this example, the contact metallurgy of choice is Zirconium as the maximum solubility of Zirconium in Copper is approximately ⅓ that of Hafnium and several hundred times less than Titanium. A memory array of the density proposed here will require at least three levels of metallurgy, preferably with a low resistance and with a high electromigration resistance. To provide high electromigration resistance, a process using nano-tube via structures may be employed. In one example where a nanotube via structure is used, the first metal level is covered with the desired insulator and vias opened. If the top surface can serve as a catalyst for nanotube deposition, it is exposed to a carbon plasma of the proper composition and the nanotubes are grown in the vias. If the top surface of the first conductor is not suitable for initiating nanotube growth then a suitable catalytic material is deposited in the via bottom. This may be done for example by electroless plating selective CVD or ion implantation. After the nanotubes are grown the top metal layer is deposited and the appropriate conducting pattern etched therein.

In each of these examples, a variety of further steps may be performed, and a variety of materials, steps, and other process elements can be changed to produce other results. For example, annealing the silicon after each diffusion of n-type material will typically result in better and more uniform diffusion with fewer defects than would be achieved by omitting this step. Similarly, certain materials used in these examples may be substituted for other materials having other electrical characteristics, such as forming metallic wordlines or bitlines rather than using carbon nanotube wordlines and bitlines.

Although certain examples shown and described here, other variations exist and are within the scope of the invention. It will be appreciated by those of ordinary skill in the art that any arrangement which is calculated to achieve the same purpose may be substituted for the specific embodiments shown. This application is intended to cover any adaptations or variations of the example embodiments of the invention described herein. It is intended that this invention be limited only by the claims, and the full scope of equivalents thereof.

1. A nanodot nonvolatile memory element, comprising
a substrate;
a source in contact with the substrate;
a drain in contact with the substrate but not in contact with the source;
a high-κ insulating layer formed on the substrate and positioned between gate region insulators formed on the substrate;
a nanocrystalline floating gate formed in the high-κ insulating layer at a distance no greater than ten nanometers from the substrate; and
a carbon nanotube control gate formed in the high-κ insulating layer at a distance no greater than twenty nanometers from the substrate.

2. The nanodot nonvolatile memory element of claim 1, wherein the substrate comprises a p-type silicon, and the source and drain comprise n-type silicon.

3. The nanodot nonvolatile memory element of claim 1, wherein the high-κ insulating layer comprises hafnium aluminum oxide (HfAlO).

4. The nanodot nonvolatile memory element of claim 1, wherein the nanocrystalline floating gate comprises a nanocrystal comprising germanium.

5. The nanodot nonvolatile memory element of claim 1, wherein the nanocrystalline floating gate comprises a nanocrystal comprising silicon.

6. The nanodot nonvolatile memory element of claim 1, wherein the nanocrystalline floating gate is between approximately three and 20 nanometers in its largest dimension.

7. The nanodot nonvolatile memory element of claim 1, wherein the distance between the nanocrystalline floating gate and the substrate is less than approximately five nanometers.

8. The nanodot nonvolatile memory element of claim 1, wherein the distance between the carbon nanotube control gate and the substrate is less than approximately 15 nanometers.

9. The nanodot nonvolatile memory element of claim 1, wherein the carbon nanotube control gate has a diameter of less than approximately ten nanometers.

10. The nanodot nonvolatile memory element of claim 1, wherein the programmed charge of the floating gate comprises five or fewer electrons.

11. The nanodot nonvolatile memory element of claim 1, wherein the gate region isolation insulator comprises silicon dioxide.

12. A method of forming a nonvolatile memory element, comprising:
forming a high-κ insulating layer on a substrate layer and positioned between gate region insulators formed on the substrate;
forming a nanocrystalline floating gate on the high-κ insulating layer, the nanocrystalline floating gate being no more than 10 nanometers in its largest dimension;
forming separate source and drain regions in the substrate, the source and drain regions physically connected by the substrate; and
forming a carbon nanotube control gate embedded in the high-κ insulating layer.

13. The method of forming a nonvolatile memory element of claim 12, the carbon nanotube control gate being no greater than 10 nanometers in diameter.

14. The method of forming a nonvolatile memory element of claim 12, the nanocrystalline floating gate being no more than 10 nanometers from the substrate.

15. The method of forming a nonvolatile memory element of claim 12, the nanocrystalline floating gate being between two and six nanometers in its largest dimension.

16. The method of forming a nonvolatile memory element of claim 12, the carbon nanotube control gate being separated from the substrate by no more than twenty nanometers.

17. The method of forming a nonvolatile memory element of claim 12, the nanocrystalline floating gates formed by depositing a conductive material in an etched nitride mask.

18. The method of forming a nonvolatile memory element of claim 17, the etched nitride mask formed by masking the nitride with a self-aligning chaperonin protein mask and etching the exposed nitride.

19. The method of forming a nonvolatile memory element of claim 12, wherein the carbon nanotube control gate comprises a wordline, and further comprising a carbon nanotube bitline.

20. The method of forming a nonvolatile memory element of claim 19, wherein the carbon nanotube wordline and bitline are formed via masks that are formed via self-aligning chaperonin proteins.

21. A nonvolatile memory, comprising:
a plurality of nanocrystalline nonvolatile memory elements, each nonvolatile memory element comprising:
a field effect transistor having a substrate with a source and a drain and a high-κ insulating layer separating a floating gate and a control gate from the substrate, the floating gate comprising a conductive element no greater than 10 nanometers in its largest dimension and separated from the substrate by no more than five nanometers, wherein the high-κ insulating layer is positioned between gate region insulators formed on the substrate;
a plurality of carbon nanotube wordlines formed in the a high-κ insulating layer and serving as the control gates for the plurality of nonvolatile memory elements the carbon nanotubes being no more than 10 nanometers in diameter and separated from the substrate by no more than 20 nanometers; and
a plurality of carbon nanotube bitlines.

22. The nonvolatile memory of claim 21, the plurality of carbon nanotube bitlines coupled via one or more bitline select transistors to one or more series strings of nanocrystalline nonvolatile memory elements.

23. The nonvolatile memory of claim 21, the plurality of carbon nanotube bitlines coupled to control logic via a plurality of carbon nanotube studs formed perpendicular to the carbon nanotube bitlines.

24. The nonvolatile memory of claim 21, the plurality of carbon nanotube wordlines coupled to memory array control logic via a plurality of carbon nanotube studs formed perpendicular to the carbon nanotube wordlines.

25. (canceled)

26. A memory array comprising an array of memory elements comprising:
a source and a drain in contact with a substrate but the source not in contact with the drain;
a nanocrystalline floating gate formed in an insulating layer formed on the substrate;
a carbon nanotube control gate formed in the insulating layer formed on the substrate; and
one or more carbon nanotube vias coupling at least one of a control gate, the source, or the drain to control circuitry.

27. The memory array of claim 26, wherein the one or more nanotube vias are coupled to at least one of the source, the drain, and the control gate through at least one of a Titanium, Zirconium, and a Hafnium conductor.

28. The memory array of claim 27, wherein the at least one of the Titanium, Zirconium, and Hafnium conductor is further coupled to aluminum.

29. The memory array of claim 28, comprising copper coupled to the aluminum.

30. A method of forming a semiconductor device, comprising:
masking a first material with a self-aligning chaperonin protein mask;
etching the exposed first material;
removing the chaperonin protein mask; and
depositing a conductive material in the etched first material.

31. The method of forming a semiconductor device of claim 30, wherein the conductive material comprises at least one flash memory floating node.

32. The method of forming a semiconductor device of claim 30, wherein the first material is a nitride mask.

33. The method of forming a semiconductor device of claim 30, further comprising forming at least one array of carbon nanotube connecting lines via masks that are formed via self-aligning chaperonin proteins.
